(19) United States
(12) Patent Application Publication
(10) Pub. No.: US 2003/0146520 A1
(43) Pub. Date: Aug. 7, 2003

(54) FLIP-CHIP PACKAGE WITH A HEAT SPREADER

(76) Inventor: JEN-KUANG FANG, PINGTUNG HSIEN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,295

(22) Filed: Jan. 7, 2003

(30) Foreign Application Priority Data
Jan. 7, 2002 (TW) 91100097

(51) Int. Cl. H01L 23/48

(52) U.S. Cl. 257/778

(57) ABSTRACT

A flip-chip package with a heat spreader includes a substrate, a chip, a heat spreader, multiple first bumps, multiple second bumps, a first fill material and a second fill material. The substrate has multiple conductive nodes formed on a surface thereof. The chip has an active surface and a corresponding backside surface. The chip further has multiple conductive pads formed on the active surface. The chip is placed over the substrate, the active surface of the chip facing the surface of the substrate. The heat spreader having a cavity is placed on the substrate, wherein the cavity of the heat spreader faces the substrate and the chip is located inside the cavity. The first bumps are placed between the conductive pads of the chip and the conductive nodes of the substrate. The second bumps are placed between the backside surface of the chip and the heat spreader. The first fill material is filled between the chip and the substrate and covers the first bumps. The second fill material is filled in the cavity of the heat spreader and covers the chip and the second bumps.

### CROSS REFERENCE TO RELATED APPLICATIONS

This application claims the priority benefit of Taiwan application serial no. 91 100097, filed on Jan. 7, 2002.

### BACKGROUND OF INVENTION

1. Field of the Invention

The invention relates in general to a flip-chip package with a heat spreader. More particularly, the invention relates to a flip-chip package with a heat spreader having excellent heat conductivity.

2. Description of the Related Art

Recently, following the changes taking place in electronics technology with each passing day, high-tech electronic products offering ease of use and multi-function have been presented to the public one after another. The nucleus of the electronic products is chips electrically connecting with other chips or passive units through a substrate. The profile of development of electronic products follows the trend of lightness, thinness, shortness and smallness. However, various problems concerning heat are generated with this trend. Generally, a heat spreader is mounted on a backside surface of a chip by a thermal conductive adhesive such that the heat can be transferred away from the chip and spread over the heat spreader and then to the outside.

FIG. 1 is a schematic cross-sectional view showing a conventional flip-chip package with a heat spreader. The process for fabricating the flip-chip package with a heat spreader is first to provide a chip 110 with an active surface 112 and a corresponding backside surface 114. The chip 110 is provided with multiple conductive pads 116 formed on the active surface 112. Further, a substrate 120 is provided with multiple conductive nodes 124 formed on a surface 122 of the substrate 120. Following this, bonding the chip 110 to the substrate 120 in a flip-chip bonding type is performed where first, multiple bumps 130 are formed on the conductive pads 116 of the chip 110. Next, the chip 110 is placed on the substrate 120, and the bumps 130 are aligned to the conductive nodes of the substrate 120. Subsequently, a reflow process is used to bond the bumps 130 to the conductive nodes 124. Thereafter, a fill material 132 is filled between the chip 110 and the substrate 120 which can cover the bumps 130. So far the formation of a flip-chip package 190 is finished. Further, a heat spreader 140 is provided with a cavity 142. A thermal conductive adhesive 150 is applied on the backside surface 114 of the chip 110. The heat spreader 140 is moved in a cavity-down attitude and the cavity 142 thereof can cover the flip-chip package 190. The top portion of the cavity 142 can keep contact with the thermal conductive adhesive 150 such that the heat can be transferred away from the chip 110 and be spread over the heat spreader 140 through the thermal conductive adhesive 150.

In the above process, since it is not easy to control the height of the bumps 130 to be at the same level, the distance between the top portion of the cavity 142 and the backside surface 114 of the chip 110 is not easily controlled. In the case where the height of the bumps 130 is relatively high, the distance between the top portion of the cavity 142 and the backside surface 114 of the chip 110 is relatively narrow. When the heat spreader 140 is pressed on the backside surface 114 of the chip 110, the thermal conductive adhesive 150 is flushed outside the backside surface 114 of the heat spreader 140. In the case where the height of the bumps 130 is relatively low, the distance between the top portion of the cavity 142 and the backside surface 114 of the chip 110 is relatively large. As a result, the thermal conductive adhesive 150 cannot keep uniform contact with the heat spreader 140 and thus the heat conductivity is bad.

### SUMMARY OF INVENTION

It is an objective according to the present invention to provide a flip-chip package with a heat spreader that has excellent heat conductivity.

It is another objective according to the present invention to provide a flip-chip package with a heat spreader that can endure relatively large allowance of the height of the bumps.

To achieve the foregoing and other objectives, the present invention provides a flip-chip package with a heat spreader. The flip-chip package with a heat spreader includes a substrate, a chip, a heat spreader, multiple first bumps, multiple second bumps, a first fill material and a second fill material. The substrate has multiple conductive nodes formed on a surface thereof. The chip has an active surface and a corresponding backside surface. The chip further has multiple conductive pads formed on the active surface. The chip is placed over the substrate, the active surface of the chip facing the surface of the substrate. The heat spreader having a cavity is placed on the substrate, wherein the cavity of the heat spreader faces the substrate and the chip is located inside the cavity. The first bumps are placed between the conductive pads of the chip and the conductive nodes of the substrate. The second bumps are placed between the backside surface of the chip and the heat spreader. The first fill material is filled between the chip and the substrate and covers the first bumps. The second fill material is filled in the cavity of the heat spreader and covers the chip and the second bumps.

According to an embodiment of the present invention, the above flip-chip package further includes an under-bump metallic layer formed on the backside surface of the chip. The under-bump metallic layer is formed with a barrier layer and a seed layer. The barrier layer is formed on the backside surface of the chip. The seed layer is formed on the barrier layer. The material constituting the barrier layer can be titanium, titanium-tungsten alloy, or chromium. The material constituting the seed layer can be copper. The material constituting the second bumps can be tin-lead alloy.

Both the foregoing general description and the following detailed description are exemplary and explanatory only and are not restrictive of the invention, as claimed.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic cross-sectional view showing a conventional flip-chip package with a heat spreader.

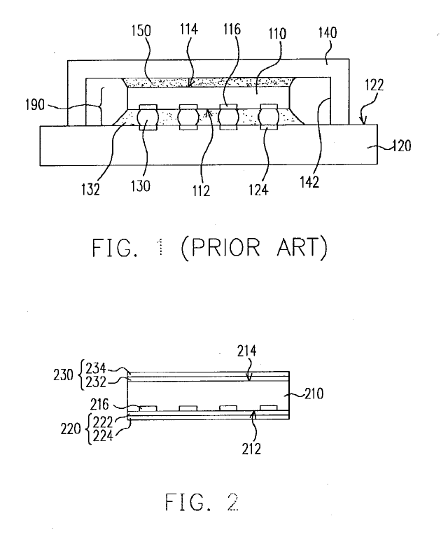

FIGS. 2-9 are schematic cross-sectional views showing a process of forming a flip-chip package with a heat spreader according to a first preferred embodiment of the present invention.

FIG. 10 is a schematic cross-sectional view showing a flip-chip package with a heat spreader according to a second preferred embodiment of the present invention.

FIG. 11 is a schematic cross-sectional view showing a flip-chip package with a heat spreader according to a third preferred embodiment of the present invention.

FIG. 12 is a schematic cross-sectional view showing a flip-chip package with a heat spreader according to a fourth preferred embodiment of the present invention.

FIG. 13 is a schematic cross-sectional view showing a flip-chip package with a heat spreader according to a fifth preferred embodiment of the present invention.

FIG. 14 is a schematic cross-sectional view showing a flip-chip package with a heat spreader according to a sixth preferred embodiment of the present invention.

### DETAILED DESCRIPTION

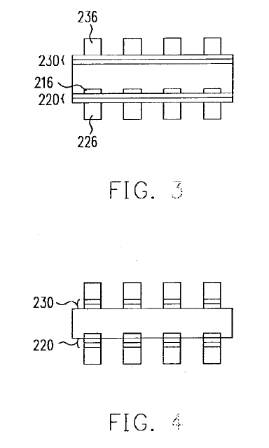

FIGS. 2-9 are schematic cross-sectional views showing a process of forming a flip-chip package with a heat spreader according to a first preferred embodiment of the present invention. First, referring to FIG. 2, a chip 210 is provided with an active surface 212 and a corresponding backside surface 214. The chip 210 is provided with multiple conductive pads 216 formed on the active surface 212 thereof. Next, a sputter process can be used to form a first barrier layer 222 onto the active surface 212 of the chip 210 and to form a second barrier layer 232 onto the backside surface 214 of chip 210. The material constituting the first barrier layer 222 and the second barrier layer 232 can be, for example, titanium, titanium-tungsten alloy, or chromium. Subsequently, an electroplating process can be used to form a first seed layer 224 onto the first barrier layer 222 and to form a second seed layer 234 onto the second barrier layer 232. The material constituting the first seed layer 224 and the second seed layer 234 can be, for example, copper. The first barrier layer 222 and the first seed layer 224 constitute a first under-bump metallic layer 220. The second barrier layer 232 and the second seed layer 234 constitute a second under-bump metallic layer 230.

Subsequently, referring to FIG. 3, a screen printing process or an electroplating process can be used to form multiple first bumps 226 on the first under-bump metallic layer 220 and to form multiple second bumps 236 on the second under-bump metallic layer 230. The placement of the first bumps 226 is aligned to that of the conductive pads 216 of the chip 210. The material constituting the first bumps 226 and the second bumps 236 can be, for example, tin-lead alloy.

Next, as shown in FIG. 3 and FIG. 4, an etching process is performed using an etchant to remove the first under-bump metallic layer 220 exposed to the outside and to remove the second under-bump metallic layer 230 exposed to the outside.

Next, referring to FIG. 5, a reflow process is performed and the first bumps 226 and the second bumps 236 are shaped like balls.

Referring to FIG. 6, a substrate 240 is provided with multiple conductive nodes 244 formed on a surface 242 of the substrate 240. Next, bonding the chip 210 to the substrate 240 in a flip-chip bonding type is performed where first, the chip 210 is placed on the substrate 240, and the first bumps 226 are aligned to the conductive nodes of the substrate 240. Subsequently, a reflow process is performed to bond the first bumps 236 to the conductive nodes 244 of the substrate 240, so the chip 210 can be bonded onto the substrate 240.

Referring to FIG. 7, a fill material 228 is filled between the chip 210 and the substrate 240 which can cover the first bumps 130.

Referring to FIG. 8, a heat spreader 250 is provided with a cavity 252. The heat spreader 250 is moved in a cavity-down attitude, the cavity 142 of the heat spreader 250 facing the substrate 240 and being aligned to the chip 210. At this moment, the heat spreader 250 is heated such that the second bumps 236, after contacting the top portion 256 of the heat spreader 250, are melted and then the second bumps 236, after cooling down, are bonded to the heat spreader 250. A lower surface 254 of the heat spreader 250 can contact the surface 242 of the substrate 240. The chip 210 is located in the cavity 252.

Next, referring to FIG. 9, a fill material 260 is filled into the cavity 252 of the substrate 250, covering the chip 210 and the second bumps 236. Preferably, the material constituting the fill material 260 can be like the material constituting a thermal conductive adhesive. With this the process of fabricating a flip-chip package with a heat sink is completed.

In the above process, since it is not easy to control the height of the first bumps 226 to be at the same level, the distance between the top portion 256 of the cavity 252 and the backside surface 214 of the chip 210 is not easily controlled. However, according to the present invention, the arrangement such that the second bumps 236 are placed between the top portion 256 of the cavity 252 and the backside surface 214 of the chip 210 has a relatively large allowance for inaccuracy of the height of the first bumps 226. In the case where the height of the first bumps 226 is relatively high, that is, the distance between the top portion 256 of the cavity 252 and the backside surface 214 of the chip 210 is relatively narrow, the second bumps 236, after being pressed by the heat spreader 250, become relatively flat, but the thermal conductivity between the chip 210 and the heat spreader 250 is still excellent. In the case where the height of the first bumps 226 is relatively low, that is, the distance between the top portion 256 of the cavity 252 and the backside surface 214 of the chip 210 is relatively large, the second bumps 236, after being pressed by the heat spreader 250, become relatively thin, but the thermal conductivity between the chip 210 and the heat spreader 250 is still excellent.

Moreover, according to the present invention, the second bumps 236 serve as the main thermal conductivity between the chip 210 and the heat spreader 250. Compared with the thermal conductive adhesive in the prior art, the second bumps 236, such as tin-lead alloy, have better thermal conductivity. Furthermore, the second bumps 236 have better electric conductivity than the thermal conductive adhesive in the prior art, so the electrical connection between the chip 210 and the heat spreader 250 is enhanced.

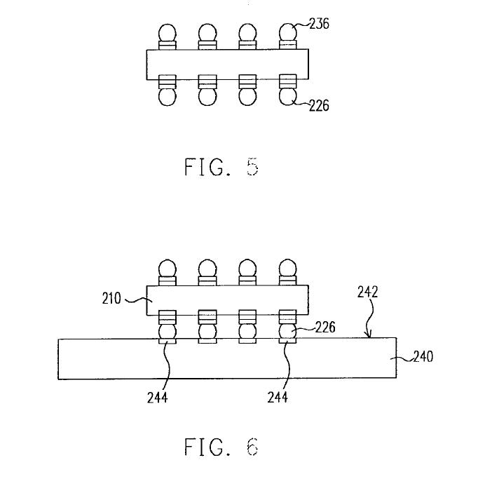

According to the above preferred embodiment, multiple second bumps are used to bond the heat spreader to the chip. However, the application of the present invention is not limited to the above description but another embodiment also can be achieved, as shown in FIG. 10. FIG. 10 is a schematic cross-sectional view showing a flip-chip package with a heat spreader according to a second preferred embodiment of the present invention. Alternatively, only one second bump 336 can be used to bond a heat spreader 350 to an under-bump metallic layer 330 on a backside surface 314 of a chip 310.

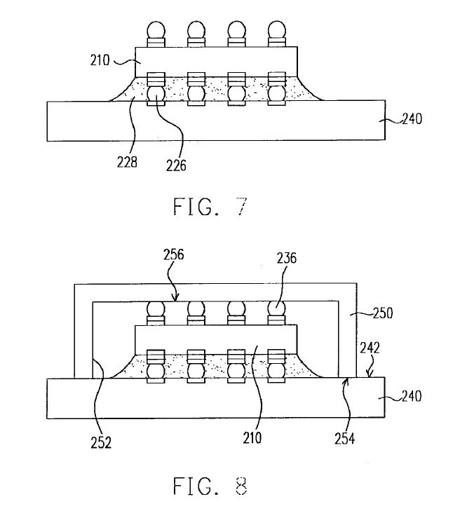

According to the above preferred embodiment, an etching process is performed using an etchant to remove the second under-bump metallic layer exposed to the outside. However, the application of the present invention is not limited to the above description but another embodiment also can be achieved as shown in FIG. 11. FIG. 11 is a schematic cross-sectional view showing a flip-chip package with a heat spreader according to a third preferred embodiment of the present invention. Alternatively, an etching process cannot be performed such that a second under-bump metallic layer 430 can cover a whole backside surface 414 of a chip 410.

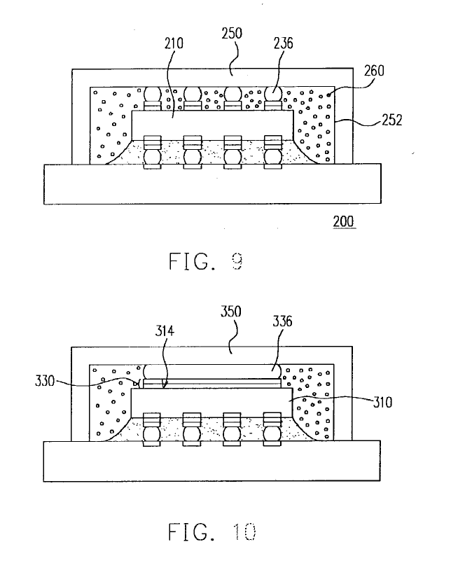

According to the above preferred embodiment, an under-bump metallic layer is formed on a backside surface of a chip. However, the application of the present invention is not limited to the above description but another embodiment also can be achieved as shown in FIG. 12. FIG. 12 is a schematic cross-sectional view showing a flip-chip package with a heat spreader according to a fourth preferred embodiment of the present invention. Alternatively, there is no under-bump metallic layer formed on a backside surface 514 of a chip 510 and multiple second bumps 536 are directly formed on the backside surface 514 of the chip 510.

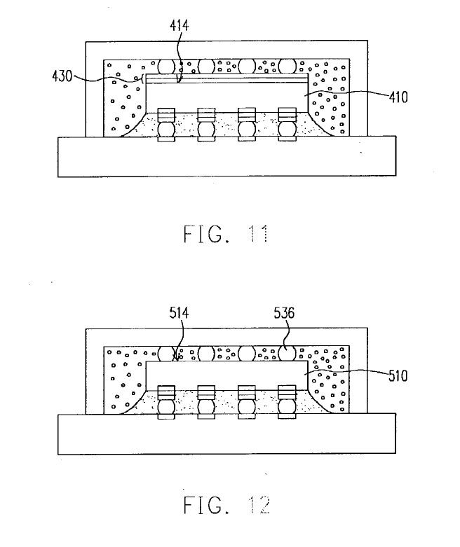

According to the above preferred embodiment, after the chip is bonded onto the substrate, a fill material is filled between the chip and the substrate. However, the application of the present invention is not limited to the above description but another embodiment also can be achieved as shown in FIG. 13. FIG. 13 is a schematic cross-sectional view showing a flip-chip package with a heat spreader according to a fifth preferred embodiment of the present invention. Alternatively, after a chip 610 is bonded onto a substrate 640, no fill material is immediately filled between the chip 610 and the substrate 640. Nevertheless, after a heat spreader 650 is mounted onto the chip 610, a fill material 660, such as an insulator, can be filled into a cavity 652 of the heat spreader 650 and can cover first bumps 626, second bumps 636 and the chip 610. Thereby, the above process according to the fifth embodiment is comparatively simple.

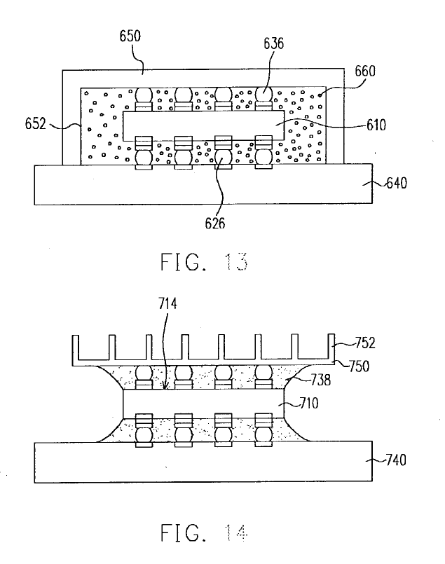

In the above preferred embodiment, a heat spreader keeps contact with a substrate. However, the application of the present invention is not limited to the above description but another type of heat spreader also can be used in the present invention. FIG. 14 is a schematic cross-sectional view showing a flip-chip package with a heat spreader according to a sixth preferred embodiment of the present invention. Alternatively, another type of heat spreader 750 can be provided with multiple fins 752 and can be mounted onto a backside surface 714 of a chip 710 without contacting a substrate 740. A fill material 738, preferably like a thermal conductive adhesive, is filled between the heat spreader 750 and the chip 710.

Those skilled in the art should know the present invention is not limited to the configuration shown in the figures but the inventive essences described in each preferred embodiment can be applied each to the other.

The main characteristic of the present invention is the arrangement that at least one bump is placed between a heat spreader and a chip. The bump bonds the heat spreader onto the chip. In a special case, if the thermal coefficient of the heat spreader is approximately similar with that of the chip, there can be no fill material filled between the chip and the heat spreader.

To sum up, the present has the following advantages:

1. Referring to the flip-chip package according to the present invention, since it is not easy to control the height of the first bumps at the same level, the distance between the top portion of the cavity and the backside surface of the chip is not easily controlled. However, according to the present invention, the arrangement that the second bumps are placed between the top portion of the cavity and the backside surface of the chip has a relatively large allowance for inaccuracy of the height of the first bumps. In the case where the height of the first bumps is relatively high, that is, the distance between the top portion of the cavity and the backside surface of the chip is relatively narrow, the second bumps, after being pressed by the heat spreader, become relatively flat, but the thermal conductivity between the chip and the heat spreader is still excellent. In the case where the height of the first bumps is relatively low, that is, the distance between the top portion of the cavity and the backside surface of the chip is relatively large, the second bumps, after being pressed by the heat spreader, become relatively thin, but the thermal conductivity between the chip and the heat spreader is still excellent.

2. Referring to the flip-chip package according to the present invention, the second bumps serve as the main thermal conductivity between the chip and the heat spreader. Compared with the thermal conductive adhesive in the prior art, the second bumps, such as tin-lead alloy, have better thermal conductivity.

3. Referring to the flip-chip package according to the present invention, the second bumps have better electric conductivity than the thermal conductive adhesive in the prior art, so the electrical connection between the chip and the heat spreader is enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A flip-chip package with a heat spreader, comprising:
a substrate having multiple conductive nodes formed on a surface thereof;
a chip having an active surface and a corresponding backside surface, the chip further having multiple conductive pads that are formed on the active surface, the chip being placed over the substrate, the active surface of the chip facing the surface of the substrate;
a heat spreader placed over the substrate, the spreader having a cavity facing the substrate, the chip located inside the cavity;
a plurality of first bumps placed between the conductive pads of the chip and the conductive nodes of the substrate;
a plurality of second bumps placed between the backside surface of the chip and the heat spreader;
a first fill material filled between the chip and the substrate and covering the first bumps; and
a second fill material filled in the cavity of the heat spreader and covering the chip and the second bumps.

2. The flip-chip package according to claim 1, further comprising an under-bump metallic layer that is formed on the backside surface of the chip.

3. The flip-chip package according to claim 2, wherein the under-bump metallic layer has a barrier layer, whose material is titanium, titanium-tungsten alloy, or chromium.

4. The flip-chip package according to claim 2, wherein the under-bump metallic layer has a seed layer, whose material is copper.

5. The flip-chip package according to claim 1, wherein the material constituting the second bumps is tin-lead alloy.

6. A flip-chip package with a heat spreader, comprising:
a substrate;
a chip having an active surface and a corresponding backside surface, the chip placed over the substrate, the active surface of the chip facing the substrate;
a heat spreader placed over the substrate;
a plurality of first bumps placed between the chip and the substrate;
at least one second bump placed between the backside surface of the chip and the heat spreader;
a first fill material covering the first bumps; and
a second fill material covering the second bumps.

7. The flip-chip package according to claim 6, further comprising an under-bump metallic layer that is formed on the backside surface of the chip.

8. The flip-chip package according to claim 7, wherein the under-bump metallic layer has a barrier layer.

9. The flip-chip package according to claim 8, wherein the material constituting the barrier layer is selected from a group consisting of titanium, titanium-tungsten alloy and chromium.

10. The flip-chip package according to claim 7, wherein the under-bump metallic layer has a seed layer.

11. The flip-chip package according to claim 10, wherein the material constituting the seed layer includes copper.

12. The flip-chip package according to claim 6, wherein the material constituting the second bump is tin-lead alloy.

13. A high thermal-conductive chip structure, comprising:
a chip having a backside surface;
a heat spreader placed over the backside surface of the chip; and
at least one bump placed between the heat spreader and the backside surface of the chip.

14. The high thermal-conductive chip structure according to claim 13, further comprising an under-bump metallic layer that is formed on the backside surface of the chip.

15. The high thermal-conductive chip structure according to claim 14, wherein the under-bump metallic layer has a barrier layer.

16. The high thermal-conductive chip structure according to claim 15, wherein the material constituting the barrier layer is selected from a group consisting of titanium, titanium-tungsten alloy and chromium.

17. The high thermal-conductive chip structure according to claim 14, wherein the under-bump metallic layer has a seed layer, whose material is copper.

18. The high thermal-conductive chip structure according to claim 17, wherein the material constituting the seed layer includes copper.

19. The high thermal-conductive chip structure according to claim 13, further comprising a fill material that covers the bump.

20. The high thermal-conductive chip structure according to claim 13, wherein the material constituting the bump is tin-lead alloy.
